(19) United States
(12) Patent Application Publication
(10) Pub. No.: US 2021/0294148 A1
(43) Pub. Date: Sep. 23, 2021

(54) Planarizing Organic Films

(71) Applicant: Tokyo Electron Limited, Minato-ku (JP)

(72) Inventors: Jodi Grzeskowiak, Cuddebackville, NY (US); Daniel Fulford, Cohoes, NY (US); Robert Brandt, Ballston Lake, NY (US)

(21) Appl. No.: 17/183,039

(22) Filed: Feb. 23, 2021

Related U.S. Application Data
(60) Provisional application No. 62/990,715, filed on Mar. 17, 2020.

(51) Int. Cl. G02F 1/1333; G03F 7/004; G03F 7/09; G03F 7/00

(52) U.S. Cl. CPC G02F 1/133357; G03F 7/0045; G03F 7/091; G03F 7/0035; G03F 7/094

(57) ABSTRACT

A method of planarizing a substrate includes receiving a substrate having structures formed on a target layer on a working surface of a substrate where the structures and the target layer are formed of different materials. Depositing a grafting material, including a solubility-shifting agent, on the substrate, the grafting material adhering to uncovered surfaces of the target layer without adhering to surfaces of the structures, depositing a fill material on the substrate that covers the grafting material, causing the solubility-shifting agent to diffuse a predetermined distance into the fill material, where the solubility-shifting agent causes the fill material to become insoluble to a predetermined solvent, and using the predetermined solvent to remove soluble portions of the fill material where the remaining portions of the fill material form a surface parallel to the working surface of the substrate.

### CROSS-REFERENCE TO RELATED APPLICATIONS

This application claims the benefit of U.S. Provisional Application No. 62/990,715, filed on Mar. 17, 2020, which application is hereby incorporated herein by reference.

### TECHNICAL FIELD

The present invention relates generally to semiconductor fabrication and, in particular embodiments, to planarizing techniques.

### BACKGROUND

In material processing methodologies (such as photolithography), creating patterned layers comprises the application of a thin layer of radiation-sensitive material, such as photoresist, to an upper surface of a substrate. This radiation-sensitive material is transformed into a relief pattern which can be used as an etch mask to transfer a pattern into an underlying layer on a substrate. Patterning of the radiation-sensitive material generally involves exposure of actinic radiation through a reticle (and associated optics) onto the radiation-sensitive material using, for example, a photo-lithography system. This exposure can then be followed by the removal of irradiated regions of the radiation-sensitive material (as in the case of positive photoresist), or non-irradiated regions (as in the case of negative resist) using a developing solvent. This mask layer can comprise multiple sub-layers.

In lithographic processes, from a depth-of-focus (DOF) perspective, it is desirable that the layer on which the photoresist system (including any antireflective, under-layer, and spin-on carbon film) is to be imaged is as flat or planar as possible. Variability in the flatness of this surface, caused by either the coating process or topography in the underlying substrate, will degrade the imaging performance resulting in critical dimension (CD) non-uniformity, worsened line edge roughness (LER), and unintentional profile tapering. In extreme cases, this can cause merging of two structures, line breaks, or absence of contact holes, which affects yield.

### SUMMARY

In accordance with an embodiment of the invention, a method of planarizing a substrate includes receiving a substrate having structures formed on a target layer of a working surface of a substrate, the structures formed of a first material, the target layer formed of a second material different from the first material; depositing a grafting material on the substrate, the grafting material adhering to uncovered surfaces of the target layer without adhering to surfaces of the structures, the grafting material including a solubility-shifting agent; depositing a fill material on the substrate that covers the grafting material; causing the solubility-shifting agent to diffuse a predetermined distance into the fill material, the solubility-shifting agent causing the fill material to become insoluble to a predetermined solvent; and using the predetermined solvent to remove soluble portions of the fill material, remaining portions of the fill material forming a surface parallel to the working surface of the substrate.

In accordance with another embodiment of the invention, a method of forming a pattern on a substrate includes depositing a grafting material over a substrate, the substrate having mandrels positioned on an underlying layer, the mandrels including a first material and the underlying layer including a second material, the second material being chemically different than the first material, the grafting material selectively adhering to uncovered surfaces of the underlying layer without adhering to uncovered surfaces of the mandrels, the grafting material that adheres to the underlying layer results in a uniform thickness of the grafting material on the underlying layer, the grafting material including an acid generator that releases acid in response to an activating energy; depositing a filler material on the substrate that fills spaces defined by the mandrels, the filler material being in contact with the grafting material, the filler material contacting the grafting material, the filler material forming a horizontal interface with the grafting material, the filler material including a third material; and applying the activating energy to the grafting material sufficient to activate the acid generator causing acid to diffuse a predetermined distance into the filler material, the acid rendering the filler material insoluble to a particular solvent; and removing soluble portions of the filler material using the particular solvent resulting in a layer of filler material on the underlying layer equal to the predetermined distance.

In accordance with another embodiment of the invention, a method of forming a pattern on a substrate includes depositing a grafting material over a substrate, the substrate including a plurality of structures formed over an underlying layer formed across a working surface of a substrate, the grafting material covering exposed portions of the underlying layer without covering surfaces of the plurality of structures; depositing a fill material on the substrate that covers the grafting material; liberating a solubility-shifting acid from the grafting material by exposing the substrate to a pattern of radiation; converting a portion of the fill material to a converted fill material by diffusing the solubility-shifting acid into the fill material; and selectively removing the remaining portions of the fill material without removing the converted fill material.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate cross-sectional views of a semiconductor device during various stages of fabrication in accordance with an embodiment of the present application, wherein FIG. 1A illustrates a semiconductor device having a non-planar topography, FIG. 1B illustrates the device after depositing a grafting material including an acid generator on uncovered portions of the substrate, FIG. 1C illustrates the device after depositing a fill material that covers the grafting material; FIG. 1D illustrates the device after liberating acid from the grafting material and diffusing it into the fill material; and FIG. 1E illustrates the device after using a solvent to remove portions of the fill material that have not undergone a change in solubility;

FIG. 2 is a flow chart illustrating an example process flow used to planarize and control the height of a film within a pattern causing topography across the surface of a substrate in accordance with an embodiment;

FIGS. 3A-3B illustrates cross sectional views of a semiconductor device during an intermediate stage of fabrication in accordance with an embodiment of the present application;

FIGS. 4A-4B illustrates cross sectional views of a semiconductor device during an intermediate stage of fabrication in accordance with an embodiment of the present application;

FIGS. 5A-5B illustrates cross sectional views of a semiconductor device during an intermediate stage of fabrication in accordance with an embodiment of the present application;

FIGS. 6A-6B illustrates cross sectional views of a semiconductor device during an intermediate stage of fabrication in accordance with an embodiment of the present application;

FIGS. 7A-7B illustrates cross sectional views of a semiconductor device during an intermediate stage of fabrication in accordance with an embodiment of the present application;

FIGS. 8A-8B illustrates cross sectional views of a semiconductor device during an intermediate stage of fabrication in accordance with an embodiment of the present application;

FIGS. 9A-9B illustrate cross-sectional views of a semiconductor device during various stages of fabrication in accordance with an embodiment of the present application, where FIG. 9A illustrates the device after depositing a fill material that covers the grafting material, and FIG. 9B illustrates the device after using a solvent to remove portions of the fill material that have not undergone a change in solubility resulting in a planarizing film having a height equal to the height of the tallest structures; and

FIGS. 10A-10B illustrates cross sectional views of a semiconductor device during an intermediate stage of fabrication in accordance with an embodiment of the present application.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Planarization is usually achieved through several methods. Planarization methods include chemical mechanical planarization (CMP), and depositing or spin-coating organic planarizing films among other techniques. The degree of planarization from these types of techniques, however, may not be adequate for the ever-advancing patterning schemes. As the feature resolution is reduced, there is an even greater need to control factors driving de-focus as much as possible. This requirement is driving the increasing demand for tighter planarization control of spin-on films. The planarity of these techniques is largely impacted by pattern density. In addition, CMP is an expensive method for planarization, whereas track-based methods, e.g. spin-coating, are generally more economical with higher through-put.

Embodiments of the present invention apply various track-based methods for planarization. In various embodiments, a method of forming a planarizing film on a substrate includes forming a grafting material that includes an acid generator on a substrate and then depositing a fill material over the substrate. A solubility changing acid is then liberated from the grafting material and is diffused into and interacts with portions of the fill material within a predetermined distance. Then, a planarized film is formed by removing the portions of the fill material outside of the predetermined distance (i.e. portions of the fill material that did not interact with the solubility changing acid) unaffected by the solubility changing acid using a solvent or a developer.

The techniques described here in various embodiments are advantageously a bottom-up planarization process. For example, the grafting material may be a self-assembled monolayer (SAM) or a polymer brush that selectively attaches to portions of an underlying layer that are uncovered by a pattern of structures. In this way the fill material may be deposited using spin-on deposition and may be deposited in a non-planar manner.

Additionally, the described techniques may be advantageously selective. For example, the solubility changing acid may be liberated upon applying radiation or heat. The radiation or heat may be selectively applied using localized techniques such as lithography techniques, laser techniques, etc. As a result, selected regions of the grafting material may be liberated in order to form a planarized surface based on the height of the structures formed on the substrate.

Further, the techniques described herein may advantageously facilitate track-based planarization. That is, the self-aligned methods of planarizing films may be compatible with track systems for semiconductor processing. Possible benefits of track system compatibility may include decreased cost, improved efficiency, and reduced complexity.

Embodiments provided below describe various methods for forming planarizing films, and in particular, bottom up methods for forming planarizing films that include diffusing a solubility changing acid into a fill material.

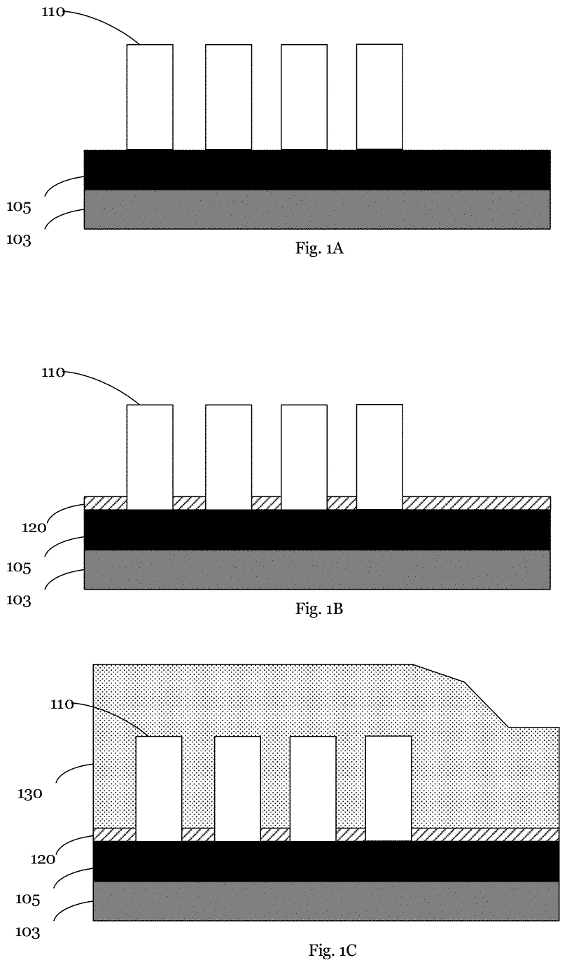

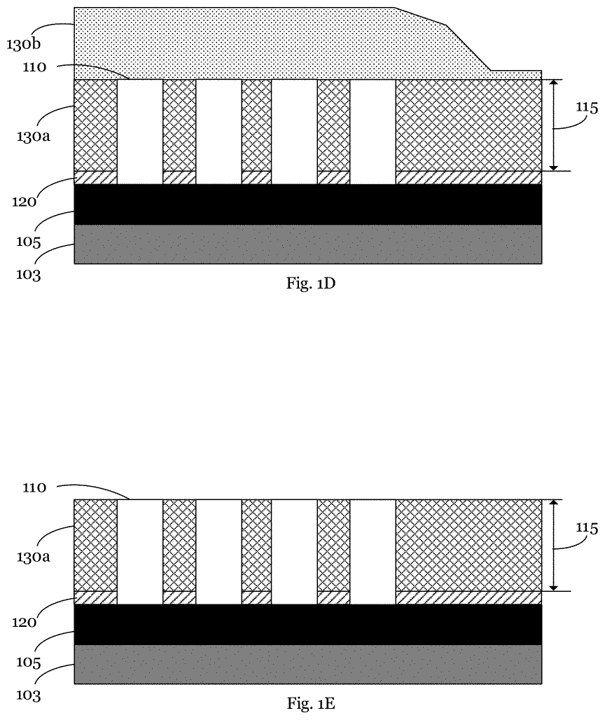

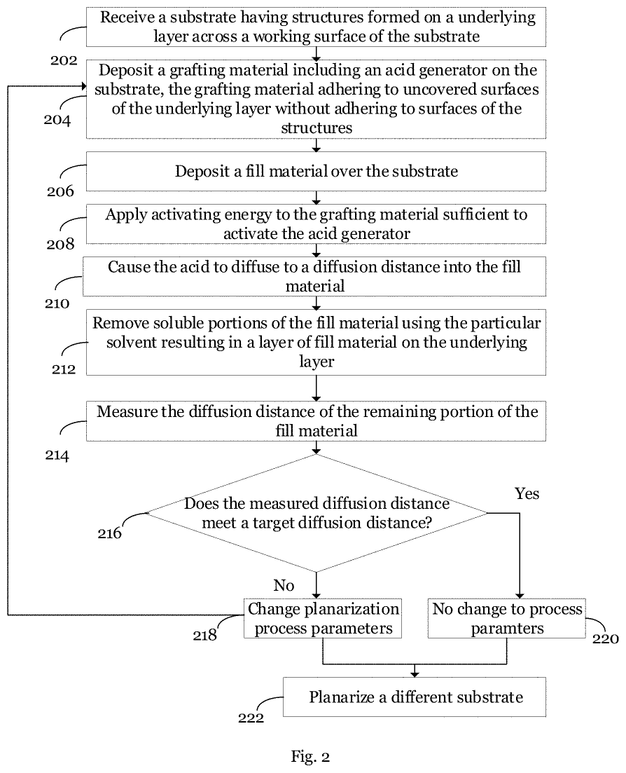

FIGS. 1A-1D illustrate cross-sectional views of a semiconductor device during various stages of fabrication in accordance with an embodiment of the present application, where FIG. 1A illustrates a semiconductor device having structures formed over an underlying layer causing a non-planar surface, FIG. 1B illustrates the device after depositing a grafting material including an acid generator on uncovered portions of the underlying layer, FIG. 1C illustrates the device after depositing a fill material over the substrate, FIG. 1D illustrates the device after the acid is diffused into the fill material and changes the solubility of certain portions of the fill material, and FIG. 1E illustrates the device after removing portions of the fill material that have not undergone a change in solubility. FIG. 2 is a flow chart illustrating an example process flow used to planarize and control the height of a film within a pattern causing topography across the surface of a substrate.

This stage of processing may be conducted after some or all process steps of the front end of the line processing has been completed. Alternately, the discussed processes may be part of mid or back end of the line processing in a typical semiconductor fabrication process.

Referring to FIG. 1A, a portion of a semiconductor device has a pattern of structures no formed on an underlying layer 105 that is formed across a working surface of a substrate 103 (block 202). The structures no only cover certain portions of the underlying layer 105 and form a non-planar surface across the substrate 103. The structures no may be any vertical semiconductor feature or mandrels. Although, in FIG. 1A, the non-planar topography is formed by three structures this is not indicative of the number of structures that may be formed across the substrate. The structures no may be any material that is to be planarized, for example, silicon nitride or silicon oxide in one embodiment. In various embodiments, the structures no may have a thickness between 5 nm to wo nm, for example, between 20 nm to 40 nm in one embodiment.

The substrate 103 may include a semiconductor substrate including substrates with epitaxial layers including silicon germanium layers. In various embodiments, the substrate 103 may comprise a bulk silicon substrate, silicon-on-insulator substrate, or other semiconductor substrates such as gallium arsenide, silicon carbide, germanium, and others as well as heterostructures such as gallium nitride on silicon.

The underlying layer 105 may be, for example, an intermetal dielectric (IMD) comprising a low-k dielectric material. In one or more embodiments, the material of the structures no is selected to be a material that is chemically different from the underlying layer 105. In other words, if the underlying layer 105 is considered the “floor,” then the structures no on the floor have a different chemical composition such that certain materials react differently with the structures no as compared to the underlying layer 105. The structures no may be formed using any conventional lithography or multipatterning process and may comprise oxide, nitride, metal, oxide-covered photoresist, hardened photoresist, silicon, and the like.

In order to form a subsequent layer of structures on the substrate 103, a subsequent lithography process requires coating the substrate 103 with a layer of material using a spin-on deposition or spin-coating process. When a substrate 103 includes a non-planar topography of densely packed structures, during the spin-coating process, the densely packed structures may push the spin-on material upward and manipulate a mass fraction of how much spin-on material fills in uncovered portions of the underlying layer 105. This causes the material to be deposited with a varying film thickness over the underlying layer 105. In other words, the deposited layer of material interacts with the topography caused by the structures no and may be deposited in a non-planar fashion.

FIGS. 1B-1E illustrate stages of the process for forming a planarizing film on the substrate 103 in which a fill material is deposited over the substrate 103 after selectively depositing a grafting material including an acid generator to uncovered surfaces of the underlying layer 105. Then a solubility shifting acid is liberated from the grafting material and diffused into the fill material to change the solubility of portions of the fill material with respect to a solvent or developer.

Referring to FIG. 1B, a grafting material 120 such as a self-aligning monolayer (SAM) is deposited over the uncovered portions of the underlying layer 105 without adhering to the structures no (block 204). The grafting material 120 may be applied in any suitable manner. In certain embodiments, the grafting material 120 is deposited through spin-on techniques or a low temperature chemical vapor deposition (CVD) process. The formation of the grafting material 120 may be advantageously selective. In various embodiments, the deposition may be controlled chemically via selective deposition. For example the grafting material 120 may comprise a material selective to the structures no so that the grafting material 120 is applied only over the uncovered portions of the underlying layer 105. The particular process steps and chemistry for depositing the grafting material 120 may vary depending on the chemistry of the underlying layer 105, the chemistry of the structures no, and the deposition technique.

The grafting material 120 may further include an acid generator. The acid generator may be a species that releases acid into the surrounding system after receiving some stimulus. For example, the acid generator may be a thermal acid generator (TAG) which releases acid in the presence of heat. The acid generator may also be a photoacid generator (PAG) which releases acid in response to radiation of a particular wavelength and/or range of energy. In one or more embodiments, the acid generator may be a free acid.

The grafting material 120 may further include a solvent such as ethanol, isopropanol (IPA), propylene glycol methyl ether acetate (PGMEA), methyl isobutyl carbinol (MIBC), 2-heptanone, decane, or the like in some embodiments.

In one or more embodiments, as noted above, the grafting material 120 may comprise a SAM that may include three generalized functionality groups: a head group, a functional group, and a body. In selecting the make-up of the SAM, the role of each of these generalized functionality groups may be considered such that an appropriate selection is made.

Head group, which also may be referred to as a ligand group, is adapted to adhere to the underlying layer 105. Broadly, the head group may be coupled or chemisorbed to the underlying layer 105. As explained above, the structures no comprise a different material than the underlying layer 105. Therefore, the chemistry of the head group is selected so that the SAM is chemically attracted only to the material comprising the underlying layer 105. In one or more embodiments, the head group may comprise a thiol (—SH), an alcohol (—OH), or a silane (e.g. —SiCl₃ or —SiRₓCl where R is a substituent group). Other possible head groups include phosphates, amino groups, and others.

The functional group which also may be referred to as a terminal group, is designed to optimize the surface condition of the SAM, allowing for subsequent spin-on layers to adhere to the grafting material 120 (e.g. provide a wetting condition). The functional group may comprise methyl (CH₃), fluorinated methyl (CF₃), amine (NH₂) or nitro (NO₂), for example, but other suitable functional groups may also be used. In some cases, a functional group may be converted to a different functional group during a crosslinking reaction. For example, a nitro functional group may be converted to amine groups by exposing the SAM to extreme ultraviolet (EUV) radiation to cause a crosslinking reaction.

The body couples the head group to the functional group and provides a desired spacing between head group and functional group. In certain embodiments, the body is a chain of molecules, such as an aliphatic chain (e.g. R¹—CH₂—R²), a fluorocarbon chain (e.g. R¹—CF₂—R²), or an aromatic chain (e.g. R¹—CF₂—R²).

Alternatively or additionally, the grafting material 120 may comprise a polymer based selective brush, i.e., polymer brush such as polynitrophenyl esters (PNPE), poly(butadiene)-b-poly(styrene) (PB-b-PS), or poly(methylmethacrylate)-g-poly(styrene) (PMMA-g-PS), Poly(2-methacryloyloxyethyl phosphorlycholine) (PMPC). A selective brush is similar to a SAM in the sense that is uses similar attachment (“Head”) groups, but different in the sense that it has a polymer back bone, such as a bottle brush structure, which makes it a bulkier molecule.

Additional functional groups (i.e. attachment groups bonded to active groups) including acid generators are attached to the grating material 120. For example, in one or more embodiments, the acid generators are attached to the SAM or polymer brush using a selective process such as “click” chemistry. Click chemistry refers to chemical reactions used to attach molecules with high specificity.

As one example, the attachment group may be an anhydride. The anhydride may attach to an amine functional group included in the grafting material 120 to form an imide (e.g. (—C(O))₂O+—NH₂→(—C(O))₂NH). An acid generator such as a photoacid generator (PAG) may then be attached to the imide. One example of a PAG active group is RSO₂ where R is a functional group. In one embodiment, the PAG active group is RSO₂ where R is a difluorobenzyl group (—(C₆H₃)F₂). In another embodiment, the PAG active group is RSO₂ where R is a nitrotrimethylbenzyl group (—(C₆H₃)(NO₂)(CF₃)). R may also be a trimethyl group (—CF₃), a perfluorobutyl group (—C₄F₉), and others.

In one or more embodiments, portions of the grafting material 120 may be unattached or weakly bound to portions of the underlying layer 105 and the structures 110. The unattached or weakly bound portions of the grafting material 120 may be removed using a solvent strip process. The solvent used in the solvent strip process may comprise propylene glycol methyl ether (PGME), propylene glycol methyl ether acetate (PGMEA), n-butyl acetate (nBA), toluene, or anisole.

In various embodiments, the thickness of the grafting material 120 is about 2 nm to 20 nm, for example, 2 nm to 5 nm in one embodiment. In one or more embodiments, although the grafting material 120 has a planar top surface, the thickness of the grafting material 120 is significantly much less than the structure 110. Hence, the grafting material 120 by itself cannot be used as the planarizing layer.

In one or more embodiments, after deposition, the grafting material 120 undergoes a post-application bake. For example, a soft bake process may be used to evaporate material of the grafting material 120 and to densify it, e.g., to evaporate some of the solvent. The soft bake process includes heating the grafting material 120 within a narrow temperature range less than 100° C., e.g., between 60° C. and 90° C.

Referring to FIG. 1C, a fill material 130 is deposited over the substrate 103 (block 206). The fill material 130 may be deposited using spin-on deposition so that it covers the working surface of the substrate 103 and the structures no. In one or more embodiments, unlike spin-on materials such as photoresist, a top surface of the fill material 130 may have a non-planar surface. For example, the top surface of the fill material 130 may include non-planar portions such as raised portions above the structures.

In one or more embodiments, after deposition, the fill material 130 undergoes a post-application bake. For example, a soft bake process may be used to evaporate material of the fill material 130 and to densify it. The soft bake process includes heating the fill material 130 within a narrow temperature range less than 150° C., e.g., between 60° C. and 90° C.

In one or more embodiments, the fill material 130 may be selected to have a chemistry compatible for changing its solubility by cross-linking with the diffused acid. Thus, the fill material 130 may comprise an acid sensitive resin such as an epoxy or hydroxyl based resin, a coating additive, and a solvent to assist in spin-on deposition. For example, the resin may be a difunctional bisphenol A/epichlorohydrin liquid epoxy resin or an epoxy phenol novolac resin with low hydrolyzable chloride content, among others. For example, the coating additive may comprise Tetrakis(methoxymethyl)glycoluril (TMMG) or Di(trimethylolpropane) (DTMP).

In other embodiments, the fill material 130 may be selected to have a chemistry compatible for changing its solubility by interacting with the diffused acid through a de-protection reaction. In various embodiments, the fill material 130 may comprise a tert-butyloxycarbonyl (t-BOC) protected polymer. In one or more embodiments, the fill material 130 may be a copolymer comprising tert-butyl acrylate (TBA) and another monomer. In other embodiments, the fill material 130 may be a terpolymer comprising TBA and two other monomers. Examples of monomers may include but are not limited to hydroxylstyrene (HS), methylmethacrylate (MMA), methyladamantylmethacrylate (MAMA), hydroxyadamantlymethacrylate (HAdMA), or methylacrylic acid (MA). The properties of the fill material 130 such as solubility, develop rate, and the like may be tuned by changing the combination of monomers and/or the molecular weight of the polymer.

Referring to FIG. 1D, as explained above, the solubility shifting acid of the grafting material 120 is liberated (block 208) and diffused into the fill material 130 to a diffusion distance 115 (block 210) from a top surface of the grafting material 120.

As explained above, the manner (i.e. heat or radiation) in which the solubility shifting acid is liberated depends on the type of acid generator. In embodiments where the acid generator is a photoacid generator (PAG), the substrate 103 is exposed to a pattern of radiation, which may be a blanket exposure or a localized exposure to actinic radiation such as ultraviolet radiation. In case of a blanket exposure, all of the top surface of the substrate receives a uniform intensity of radiation, however, only the grafting material 120 undergoes transformation after receiving this radiation. The blanket exposure may be performed using a conventional lithography tool as well as other scanning/printing tools.

In certain embodiments, the pattern of radiation may be localized over the portions underlying layer 105 covered by the grafting material 120. For example, a localized exposure may be used when the grafting material 120 has a pattern dependent uneven surface, e.g., thicker or thinner around dense features. In such cases, the amount of acid to be liberated may be tuned to compensate for the uneven thickness of the grafting material 120. In other words, the intensity of radiation has a pattern dependence so as to change the amount of acid liberated. In another embodiment, a center to edge exposure may be varied to account for the center-to-edge across wafer variations of patterned features and etch non-uniformities.

In case of a localized exposure, prior to the exposure, the substrate 103 is aligned with the tool exposing the substrate to the radiation. In various embodiments, optical alignment with an alignment mark may be used. In another embodiment, the structures no formed across the substrate 103 may be used to align the substrate 103.

In one or more embodiments, the substrate may be exposed locally using a mask-less lithography tool, such as a direct-write lithography tool. In one or more embodiments, direct write lithography methods such as digital light projection (DLP), grating light valve lithography, electron beam lithography, plasmonic lithography, focused ion beam (FIB) lithography, or nanoimprinting may be used to form the exposure pattern of the radiation. For example, the pattern of radiation may be formed and projected using a direct write lithography process in a dedicated direct writing machine. In other embodiments, the pattern of radiation may be localized using a traditional mask in a dedicated tool.

In one or more embodiments, where the acid generator is a thermal acid generator (TAG), the solubility shifting acid may be liberated using a polymerization bake on an annealing tool such as a hot plate or a furnace such as rapid thermal annealer. In one or more embodiments, the polymerization bake temperature may be within a range between 90° C. and 250° C. and may be conducted between 10 s and 120 s.

Then, after liberating the solubility shifting acid, the solubility shifting acid may diffuse to a diffusion distance 115 into the fill material 130 (block 210) from the top surface of the grafting material 120.

As explained above, the solubility shifting acid interacts with the fill material 130 by either cross-linking or de-protecting the fill material 130 within the diffusion distance 115 to change its solubility with respect to a solvent or a developer. In various embodiments, the diffusion distance 115 of the solubility shifting acid is designed to be generally equal the height of the cross-linked or de-protected portions of the fill material 130 with respect to a horizontal plane across the substrate 103 (e.g. the underlying layer 105). In other words the diffusion distance 115 may equal the height of the cross-linked or de-protected portions of the fill material (first portion 130a of the fill material in FIG. 1D). In one or more embodiments, the diffusion distance 115 may be within a range of 10 nm to 150 nm.

Notably, in various embodiments, while the solubility shifting acid may diffuse beyond the diffusion distance 115, the concentration of the solubility shifting acid outside the diffusion distance 115 may not be sufficient to react with the fill material 130.

The solubility shifting acid may be diffused using a high temperature diffusion baking process after liberating the solubility shifting acid. In one or more embodiments, the diffusion baking temperature may be within a temperature range of 90° C. and 250° C. In various embodiments, the diffusion time for the baking may be selected so that the diffusion distance 115 is about the square root of the product of the diffusivity of the solubility shifting acid in the fill material 130 and the diffusion time. In one or more embodiments, the baking may be performed between 10 s and 120 s. In further embodiments, the baking may be performed between 1 min and 10 mins.

In various embodiments, the desired diffusion distance 115 of the solubility shifting acid may be defined to match the height of the structures no. For example, if the diffusion distance 115 is too high or too low, the resulting planarizing film may form an undesirable surface lacking the structures no or a non-planar surface. In other embodiments, the desired diffusion distance 115 may be defined as a height greater than or less than the height of the structures 110. For example, in one or more embodiments, the planarizing film may be used as a sacrificial protection layer. Advantageously, the diffusion distance 115 may be tuned based on the diffusion baking process parameters such as the diffusion baking time or temperature. Also, the diffusion distance 115 may be tuned by changing acid generator properties such as the molecular weight and type of acid as well as changing fill material 130 properties such as composition, molecular weight, etc.

In one or more embodiments where the acid generator is a PAG, the diffusion distance 115 may also be tuned by the exposure dose of the radiation defined by the masked or mask-less lithography tool by controlling the localized exposure as also discussed above. In other words, the exposure dose of the radiation over each of the portions of the grafting material 120 may be tuned to control the amount of acid liberated from the PAG and allow for different diffusion distances across the substrate.

Referring to FIG. 1E, a developing step is then executed (block 212). The fill material is rinsed with a solvent or developer to remove any unreacted filler material 130b. In one or more embodiments, the rinse may comprise the casting solvent(s), aqueous developers, n-butyl acetate (NBA), propylene glycol methyl ether (PGME), phenol-based strippers, acetone, trichloroethylene, and others. This provides a planarized surface ready to receive additional processing, such as applying a lithographic film for additional patterning, hardmask, etc.

Referring back to FIG. 1D, after liberating and diffusing the acid, the first portion of the fill material 130a included in the diffusion distance 115 is now insoluble to the given solvent or developer. This may be because the fill material 130 is now cross-linked in the first portion of the fill material 130a after reacting with the acid from the grafting material 120. On the other hand, the second portion of the fill material 130b is soluble in the solvent or developer. Thus only the second portion of the fill material 130b is stripped away during the development leaving a substantially planar surface.

Embodiments of the present invention, however, do contemplate an additional timed etch process or a chemical planarization process when the diffusion distance 115 may not exactly match the height of the structures no. In such embodiments, the structures no or the first portion of the fill material 130a/structures no may be selectively removed to achieve a planar surface.

The further steps of a planarization control loop will now be described and may be performed for test wafers or after a batch of wafers are processed using blocks 214-222.

In various embodiments, after the developing step, the diffusion distance 115 may be measured (block 214). The diffusion distance 115 may be measured with an optical technique or an electron microscopy technique.

The measured diffusion distance 115 may be compared to a target diffusion distance (block 216). For example, the target diffusion distance may be based on the thickness of the structures no and the thickness of the grafting material 120 being applied. If the measured diffusion distance 115 does not meet the target diffusion distance, the diffusion distance 115 may be tuned, i.e., increased or decreased (block 218). Generally, as explained above, the diffusion distance 115 may be tuned by changing process parameters such as the properties of the acid generator along with the solubility shifting acid, the properties of the fill material, the decomposition bake time/temperature of the TAG or the exposure dose of the PAG, and the diffusion bake time/temperature. In addition, the thickness of the grafting material 120 may also be increased or decreased as it changes the total amount of acid that may be liberated. This tuning may be performed by experimentally forming a lookup table that may be used to identify the proper parameters for a given deviation in the diffusion distance 115 from the target diffusion distance.

Further wafers may be processed with the adjusted parameters. For example, after adjusting the process parameters, a new substrate having the structures no formed at the same stage of processing is planarized using the process described above (block 222).

In response to determining that the measured diffusion distance meets a target diffusion distance, no changes are made to process parameters (block 220). Irrespective of either determination, subsequent wafers may be planarized.

In one or more embodiments, as explained above, the diffusion distance may be configured to be greater than the height of the structures no.

Embodiments of this application contemplate the existence of across die variations and/or center-to-edge across wafer variations in each wafer being processed. For example, different regions on the substrate may have structures that are different in size or spacing (pitch) that can cause pattern dependent variations. Embodiments of the present application may be advantageously applied to reduce these variations. In addition, embodiments of the present application may be used to reveal (open) certain features in one region. Similarly, in certain embodiments, features in certain locations may be blocked (protected). Accordingly, embodiments of the present application may be applied to open certain features while blocking features in another location. Various embodiments are described below in more detail.

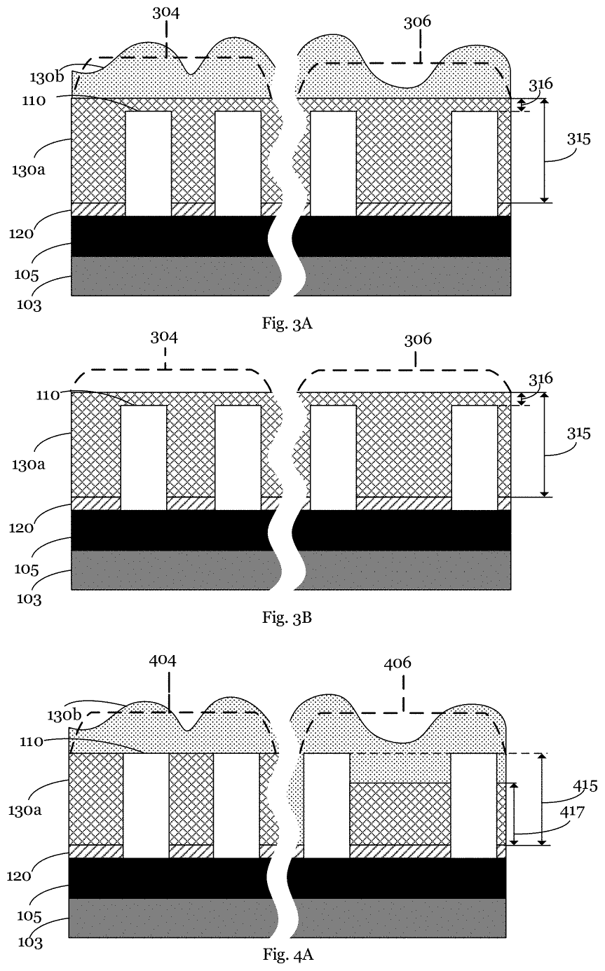

FIGS. 3A-3B illustrates cross sectional views of a semiconductor device during an intermediate stage of fabrication in accordance with an embodiment of the present application.

In the illustration of the FIG. 3A, the structures no may be more densely packed over a first portion of the substrate 304 (tighter pitch) than a second portion of the substrate 306 (or vice versa). In one or more embodiments, the structures no on both portions of the substrate 103 may have a same critical dimension or a different critical dimension. In other embodiments, the structures 110 on both portions of the substrate 103 may have the same packing density (same pitch).

Although FIG. 3A illustrates two portions of the substrate 103 with different packing densities, the number of different packing densities that may be formed across the substrate 103 is not limited by this disclosure.

In various embodiments, as illustrated in FIG. 3A, the solubility shifting acid may be liberated and diffused into the fill material 130 to a diffusion distance 315 that may be configured to be greater than the height of the structures 110.

In various embodiments, the diffusion distance 315 may be configured to be greater than the height of the structures no by a specific overfill height 316. The diffusion distance 315 including the specific overfill height 316 may be configured based on process parameters such as the properties of the acid generator along with the solubility shifting acid, the properties of the fill material, the polymerization bake time/temperature of the TAG or the exposure dose of the PAG, and the diffusion bake time/temperature.

Referring to FIG. 3B, after diffusing the solubility shifting acid into first portions of the fill material 130a included in the diffusion distance 315, which now includes the specific overfill height 316, the second (e.g. unreacted) portions of fill material 130b may be removed by a subsequent solvent or developer. Advantageously, the top surface of the remaining fill material 130a is now planar and does not need a further planarization process.

Embodiments of the invention may also contemplate situations in which the diffusion distance of the solubility shifting acid may be controlled across different portions of the substrate 103 when the grafting material 120 includes a photoacid generator (PAG). Advantageously, as described above, any suitable quantity of changes of the diffusion distance (e.g. the height of the film) may be controlled across a substrate by exposing different portions of the grafting material including a PAG to different doses of radiation. Various embodiments are discussed below.

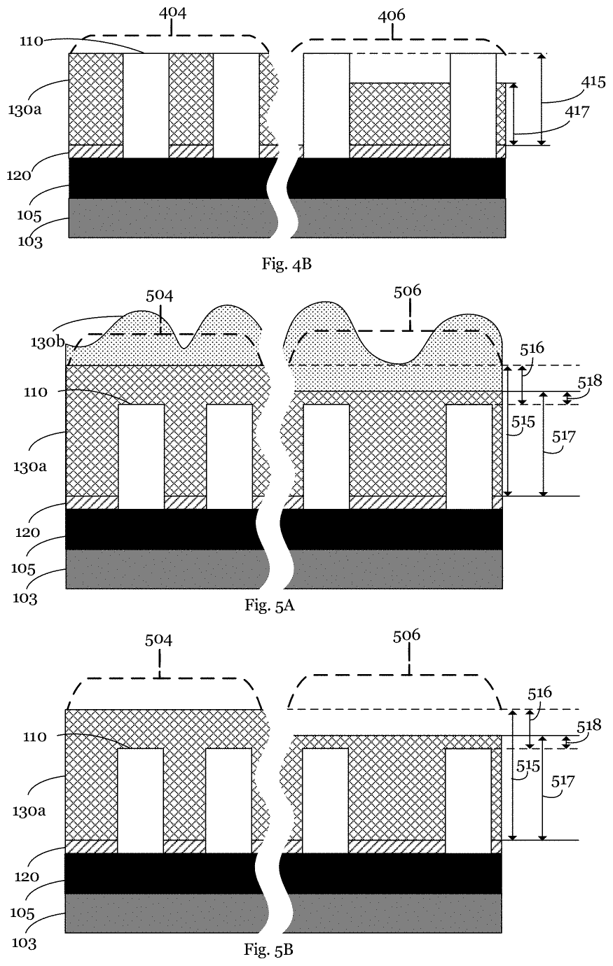

FIGS. 4A-4B illustrate cross sectional views of a semiconductor device during an intermediate stage of fabrication in accordance with an embodiment of the present application.

As previously explained, embodiments of the present application may be also applied to account for non-uniformities present in subsequent processing steps.

Referring to FIG. 4A, the diffusion distance between each of the structures no may be individually controlled by the pattern of radiation used to liberate the solubility shifting acid from the PAG. In other words, the pattern of actinic radiation may be controlled to expose different portions of the grafting material 120 to different doses of radiation to liberate more/less of the solubility shifting acid. In the illustrated example in FIG. 4A, the dose of actinic radiation may be configured to liberate a greater amount of acid in the first portion of the substrate 404 compared to the second portion of the substrate 406 to allow for a greater diffusion distance (or vice versa).

In various embodiments, the pattern of actinic radiation may be controlled using masked or mask-less lithography methods in the same manner described in FIG. 1D.

As illustrated in FIG. 4A the different amounts of liberated acid may result in a first diffusion distance 415 over a first portion of the substrate 404 that is equal to the height of the structures no and a second diffusion distance 417 over a second portion of the substrate 406 that is less than the height of the structures 110 (or vice versa).

Although the illustrated example in FIG. 4A shows only two changes in diffusion distance, the number of changes in diffusion distance across a substrate is not limited by this disclosure. Any suitable number of changes in diffusion distance may configured by the exposure pattern of actinic radiation.

Referring to FIG. 4B, the second (e.g. unreacted) portions of fill material 130b may be removed by a subsequent solvent or developer. In one or more embodiments, this may result in a film formed on a substrate 103 having a first height corresponding to the first diffusion distance 415 over the first portion of the substrate 404 and a second height corresponding to the second diffusion distance 417 over the second portion of the substrate 406.

Advantageously, as previously mentioned, the differences between the first diffusion distance 415 and the second diffusion distance 417 may be controlled to account for non-uniformities in subsequent processing steps. For example, an etching process to remove the structures no across the substrate 103 may have a non-uniform etch rate (e.g. a faster etch rate in the center of a substrate than on the edges). Therefore, the diffusion distance across the substrate may be configured provide extra protection to the underlying layer 105 in the center of substrate (e.g. a thicker film) to prevent gouging of the underlying layer 105.

Subsequently an etching process, such as a mandrel pull etch used to remove the structures 110, may have a non-uniform center-to-edge etch rate (e.g. a faster etch rate in the center of a substrate than on the edges). In other words, in one or more embodiments, an etching process may have a faster etch rate over the first portion of the substrate 404 than the second portion of the substrate 406 (or vice versa). Advantageously, the first diffusion distance 415 may be configured to be greater than the second diffusion distance 417 to account for the difference in etch rates. One advantage of this is that a thicker film may be formed over the first portion of the substrate 404 to further protect the underlying layer 105 on the first portion of the substrate 404 from gouging due to the faster etch rate.

FIGS. 5A-5B illustrate cross sectional views of a semiconductor device during an intermediate stage of fabrication in accordance with an embodiment of the present application.

In various embodiments illustrated with FIGS. 5A-5B, a film having differing heights across the substrate 103 may be formed, with each of the differing film heights being greater than the height of the structures no.

Referring to FIG. 5A, in one or more embodiments, the solubility shifting acid of the grafting material 120 may be diffused to a first diffusion distance 515 and a second diffusion distance 517 that are greater than the height of the structures no. In other words, a film may be formed across the substrate 103 having a first height (e.g. first diffusion distance 515) over a first portion of the substrate 504 and a second height (e.g. second diffusion distance 517) over the second portion of the substrate 506.

As illustrated in FIG. 5A, the first diffusion distance 515 over the first portion of the substrate 504 may include a first overfill height 516 corresponding to the difference between the first diffusion distance 515 and the height of the structures no. The second diffusion distance 517 may include a second overfill height 518 that may be less than the first overfill height 516 and may correspond to the difference between the height of the second diffusion distance 517 and the height of the structures no. In other embodiments, the second overfill height 518 (along with the second diffusion distance 517) may be greater than the first overfill height 516 (along with the first diffusion distance 515). The solubility shifting acid may be liberated, diffused, and controlled in the same manner described in FIG. 4A.

Referring to FIG. 5B, after diffusing the solubility shifting acid into first portions of the fill material 130a included in the first diffusion distance 515 and the second diffusion distance 517, the second (e.g. unreacted) portions of fill material 130b may be removed by a subsequent solvent or developer. This may result in a film having differing heights with each of the differing film heights being greater than the height of the structures no.

Subsequent processing may be used to perform a tone pattern reversal. In one or more embodiments, the film may be etched back to reveal the structures no. However, as previously mentioned, there may be a non-uniform etch rate across the substrate 103. For example, in one or more embodiments the first portion of the substrate 504 may have a greater etch rate than the second portion of the substrate 506. Therefore, the first diffusion distance 515 (e.g. first overfill height 516) may be configured to be greater that the second diffusion distance 517 (e.g. second overfill height 518) so that the film height is equal across the substrate 103 post etch back. Then once the structures 110 are revealed, they may be etched out, resulting in an opposite tone pattern of features formed in the film. Advantageously, a tone pattern reversal may be used to form smaller lines or form a pattern of features with an improved surface roughness.

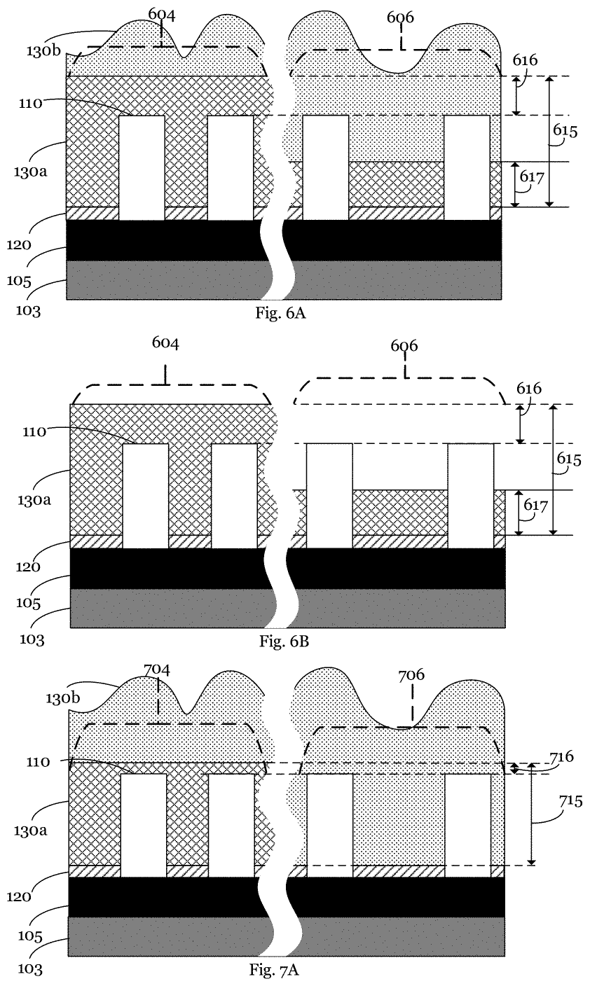

FIGS. 6A-6B illustrates cross sectional views of a semiconductor device during an intermediate stage of fabrication in accordance with an embodiment of the present application.

In certain embodiments, diffusion distances in some (but not all) locations may be greater than the height of the structures 110. Such embodiments may be used to protect one region of the substrate while opening features in another region for processing. In other words, one region is masked after this process.

Referring to FIG. 6A, in one or more embodiments, the solubility shifting acid of the grafting material 120 may be diffused to two different diffusion distances with only one diffusion distance being greater than the height of the structures 110. In other words, the first diffusion distance 615 over a first portion of the substrate 604 may be greater than a second diffusion distance 617 over a second portion of the substrate 606 and the height of the structures 110. In one or more embodiments, the second diffusion distance 617 may be less than the height of the structures 110.

As illustrated in FIG. 6A, the first diffusion distance 615 over the first portion of the substrate 604 may include a first overfill height 616 corresponding to the difference between the first diffusion distance 615 and the height of the structures 110. In one or more embodiments, the second diffusion distance 617 may be greater than the height of the structures no and include an overfill height, while the first diffusion distance 615 is less than the height of the structures 110. The solubility shifting acid may be liberated, diffused, and controlled in the same manner described in FIG. 4A.

Referring to FIG. 6B, the second (e.g. unreacted) portions of fill material 130b may be removed by a subsequent solvent or developer. In one or more embodiments, this may result in a film having a first height greater than the height of the structures 110 over a first portion of a substrate 604 and a second height less than the height of the structures 110 on a second portion of the substrate 606 (or vice versa).

Advantageously, by controlling the diffusion distances across the substrate, structures formed on certain portions of the substrate may be protected entirely, while the top portions of structures formed in other parts of the substrate are revealed. One advantage of this is that it allows for subsequent processes, such as reactive ion etching or deposition, to only affect the tops of the revealed structures 110. In other words, the structures no formed on the second portion of the substrate 606 may undergo additional processing while the structures 110 formed on the first portion of the substrate 604 remain protected. For example, in one or more embodiments, the tops of the structures no formed over the second portion of the substrate 606 may be fully removed, resulting in the “cutting” of the structures no to form the final metallization pattern.

Embodiments of the invention may also contemplate situations in which a bottom-up film may be only formed over certain portions of a substrate.

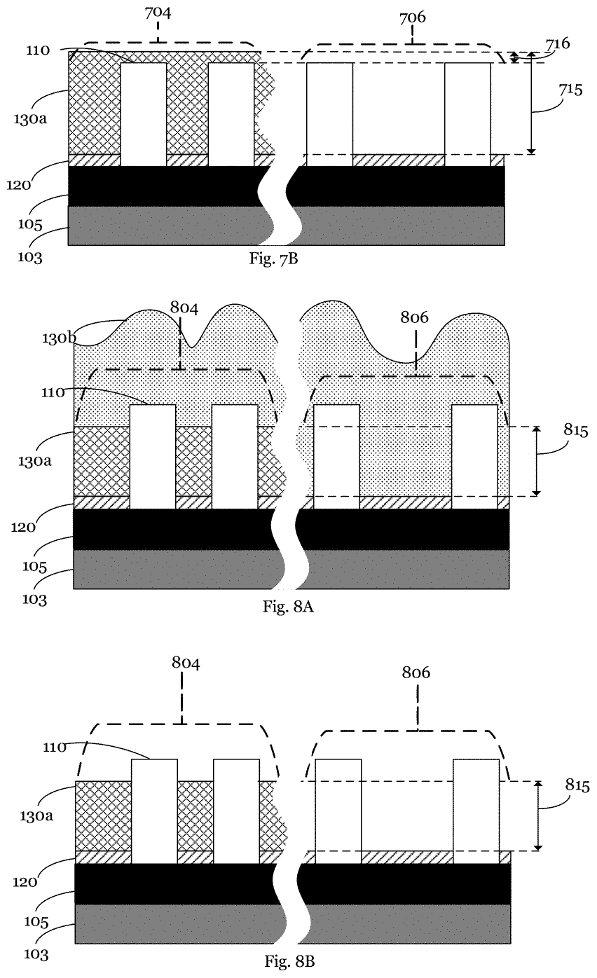

FIGS. 7A-7B illustrate cross sectional views of a semiconductor device during an intermediate stage of fabrication in accordance with an embodiment of the present application.

While the prior embodiment partially opened up certain regions, in further embodiments, all of one or more regions may be opened up. This is further illustrated in FIGS. 7A-7B described below.

Referring to FIG. 7A in one or more embodiments, the solubility shifting acid of the PAG may only be liberated and diffused over the first portion of the substrate 704. As described above, because the grafting material 120 only comprises a PAG, the pattern of actinic radiation used to liberate the solubility shifting acid may be patterned to only expose the first portion of the substrate 704. Therefore, when the substrate 103 undergoes the high temperature diffusion bake, the liberated solubility shifting acid from the first portion of the substrate 704 may be diffused into the fill material to a diffusion distance 715. In other embodiments, the pattern of actinic radiation may be patterned to liberate acid only from the second portion of the substrate 706.

Referring to FIG. 7B, the second (e.g. unreacted) portions of fill material 130b may be removed via a solvent or developer while the first portions of the fill material 130a included in the first diffusion distance 715 remain. This may result in a film that only covers the first portion of the substrate 704 (or vice versa). In various embodiments, after removing the second (e.g. unreacted) portions of fill material 130b, the portions of the grafting material 120 that were not exposed to the pattern of actinic radiation (e.g. the grafting material 120 disposed on the second portion of the substrate 706) may be selectively removed.

In various embodiments, the diffusion distance 715 of the solubility shifting acid liberated in specific portions of the grafting material 120 may be controlled using the process parameters discussed above such as the properties of the acid generator along with the solubility shifting acid, the properties of the fill material, the exposure dose of the PAG, and the diffusion bake time/temperature. For example in various embodiments, the diffusion distance 715 may be configured to be less than, greater than, or equal to the height of the structures no.

Subsequently, structures 110 on selected portions of the substrate 103 (e.g. the second portion of the substrate 706) may be trimmed, removed, or functionalized. For example, in various embodiments, the structures 110 on the second portion of the substrate 706 may be trimmed removed, or memorized into the underlying layer 105 using an etching process (wet or dry) while the first portion of the substrate 704 remains unaffected. In one or more embodiments, additional material may be deposited only on the structures 110 of the second portion of the substrate 706 such as dielectric films or surface treatment agents that may change the wettability or functionalization of the structures no such as a SAM or an Hexamethyldisilazane (HMDS)-like reagent. In other embodiments, spin-on coatings such as spin on glass, a SAM containing material, or the like, may be deposited on the second portion of the substrate 706.

FIGS. 8A-8B illustrate illustrates a cross sectional view of a semiconductor device during an intermediate stage of fabrication in accordance with an embodiment of the present application.

While not explicitly shown, embodiments of the present embodiment may also partially open the first region while fully opening up the second region.

Referring to FIG. 8A, in one or more embodiments, the solubility shifting acid may be diffused to a diffusion distance 815 less than the height of the structures 110 over only a first portion of the substrate 804.

As explained above, only the solubility shifting acid may be liberated only over the first portion of the substrate 804, by only exposing the first portion of the substrate 804 to radiation. Then, after liberating the solubility-shifting acid, the solubility shifting acid may be diffused to a diffusion distance 815 over the portion of the substrate 804 using a high temperature diffusion bake. In various embodiments, the height of the diffusion distance 815 may be configured to be less than the height of the structures no based on the process parameters discussed above.

Referring to FIG. 8B, the second (e.g. unreacted) portions of fill material 130b may be removed via a solvent or developer while the first portions of the fill material 130a included in the first diffusion distance 815 remain. This may result in a film that only covers the first portion of the substrate 804 (or vice versa) with a height less than the height of the structures no. In one or more embodiments, after removing the second (e.g. unreacted) portions of fill material 130b, the portions of the grating material 120 within the second portion of the substrate 806 (e.g. the uncovered portions of the grafting material 120) may be removed.

Subsequently, the removed portions of the grafting material 120 on the second portion of the substrate 806 may allow the pattern formed by the structures no on the second portion of the substrate 806 to be used as an etch mask to transfer a pattern of features into the underlying layer 105. However, as previously mentioned, the etch rate may be non-uniform across the substrate 103. For example, in one or more embodiments, the etching process may have a faster etch rate over the first portion of the substrate 804 than the second portion of the substrate 806 (or vice versa). Advantageously, forming a film to a specific diffusion distance only over the first portion of the substrate 804 may provide extra protection to the first portion of the substrate 804 to ensure the all the structures no are the same height after the etch process.

Embodiments of the invention may also contemplate situations in a planarizing film is formed over structures of differing heights.

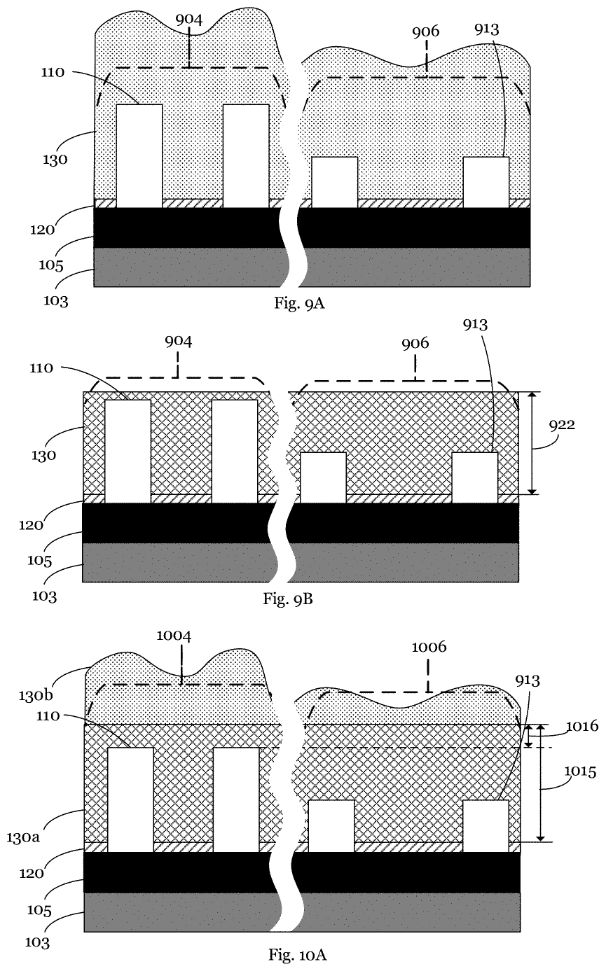

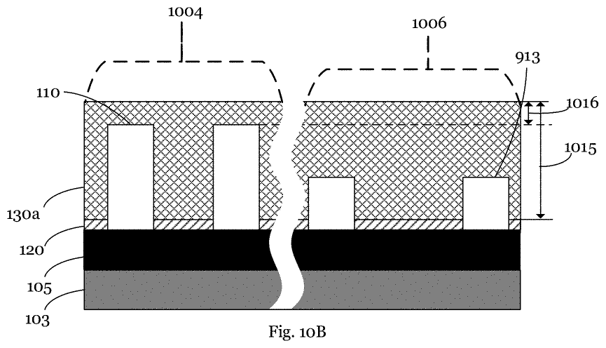

FIGS. 9A-9B illustrate cross-sectional views of a semiconductor device during various stages of fabrication in accordance with an embodiment of the present application, where FIG. 9A illustrates the device after depositing a fill material that covers the grafting material, and FIG. 9B illustrates the device after using a solvent to remove portions of the fill material that have not undergone a change in solubility resulting in a planarizing film having a height equal to the height of the tallest structures.

Referring to FIG. 9A, a portion of a semiconductor device has first structures no of a first height and second structures 913 of a second height formed on an underlying layer 105 that is formed across a working surface of a substrate 103. In various embodiments, the first structures no are formed over a first portion of the substrate 904 and the second structures 913 are formed over a second portion of the substrate 906. In one or more embodiments, the first structures no may be more densely packed than the second structures 913 (or vice versa). In various embodiments, the second structures 913 may comprise the same material and may be formed in the same manner as the first structures no.

Although FIG. 9A illustrates two portions of a substrate comprising structures of two different heights, this is not indicative of the number of height changes between structures that may be formed across the surface of the substrate 103.

Similarly, although FIG. 9A illustrates two different packing densities across the substrate 103, the number of different packing densities formed across the substrate is not limited by this disclosure.

Referring to FIG. 9B, the solubility shifting acid of the grafting material 120 is liberated and diffused into the fill material 130 to a diffusion distance 922. In one or more embodiments, the diffusion distance 922 may be configured to be equal to the structure with the greatest height. Therefore, as illustrated in FIG. 9B, the diffusion distance is approximately equal to the height of the first structures no (e.g., the tallest structures). The diffusion distance 922 is analogous to the diffusion distance 115 discussed in FIG. 1D and its description is incorporated by reference without being repeated.

In various embodiments, as discussed above, the diffusion distance 922 may be controlled based on the process parameters discussed above.

Referring to FIG. 9B, the second (e.g. unreacted) portions of fill material may be removed by a subsequent solvent or developer. The developing step is analogous to the developing step described in FIG. 1E and its description is incorporated by reference and not repeated.

FIGS. 10A-10B illustrate cross sectional views of a semiconductor device during an intermediate stage of fabrication in accordance with an embodiment of the present application.

Embodiments of the present invention also contemplate situations where a bottom-up planarizing film overfills the tallest structure across a substrate including structures of unequal heights. Unlike prior embodiments, the features formed on the substrate have different heights.

Referring to FIG. 10A, in various embodiments, the solubility shifting acid may be diffused to a diffusion distance 1015 greater than the height of the first structures 110 (i.e. the taller structures). In one or more embodiments, the diffusion distance 1015 may be greater than the height of the first structures 110 by a specific overfill height 1016 based on the process parameters discussed above.

Referring to FIG. 10B, the second (e.g. unreacted) portions of fill material may be removed by a subsequent solvent or developer. In one or more embodiments, this may result in a film formed on a substrate 103 having a height greater than the height of the first structures 110.

Accordingly, a planarized surface is formed despite the differences in heights of the structures 110 and is now ready to receive additional processing.

Example embodiments of the invention are summarized here. Other embodiments can also be understood from the entirety of the specification as well as the claims filed herein.

Example 1. A method of planarizing a substrate, the method including: receiving a substrate having structures formed on a target layer of a working surface of a substrate, the structures formed of a first material, the target layer formed of a second material different from the first material; depositing a grafting material on the substrate, the grafting material adhering to uncovered surfaces of the target layer without adhering to surfaces of the structures, the grafting material including a solubility-shifting agent; depositing a fill material on the substrate that covers the grafting material; causing the solubility-shifting agent to diffuse a predetermined distance into the fill material, the solubility-shifting agent causing the fill material to become insoluble to a predetermined solvent; and using the predetermined solvent to remove soluble portions of the fill material, remaining portions of the fill material forming a surface parallel to the working surface of the substrate.

Example 2. The method of example 1, where a top surface of the fill material after development is planar with a top surface of the structures.

Example 3. The method of one of examples 1 or 2, where a top surface of the fill material after development has a z-height below a z-height of a top surface of the structures.

Example 4. The method of one of examples 1 to 3, where the solubility-shifting agent is a free acid.

Example 5. The method of one of examples 1 to 4, where the solubility-shifting agent is a thermal acid generator.

Example 6. The method of one of examples 1 to 5, where the solubility-shifting agent is a photoacid generator.

Example 7. The method of one of examples 1 to 6, where the grafting material includes a self-assembled monolayer (SAM).

Example 8. The method of one of examples 1 to 7, where the grafting material includes a polymer brush.

Example 9. A method of forming a pattern on a substrate, the method including: depositing a grafting material over a substrate, the substrate having mandrels positioned on an underlying layer, the mandrels including a first material and the underlying layer including a second material, the second material being chemically different than the first material, the grafting material selectively adhering to uncovered surfaces of the underlying layer without adhering to uncovered surfaces of the mandrels, the grafting material that adheres to the underlying layer results in a uniform thickness of the grafting material on the underlying layer, the grafting material including an acid generator that releases acid in response to an activating energy; depositing a filler material on the substrate that fills spaces defined by the mandrels, the filler material being in contact with the grafting material, the filler material contacting the grafting material, the filler material forming a horizontal interface with the grafting material, the filler material including a third material; and applying the activating energy to the grafting material sufficient to activate the acid generator causing acid to diffuse a predetermined distance into the filler material, the acid rendering the filler material insoluble to a particular solvent; and removing soluble portions of the filler material using the particular solvent resulting in a layer of filler material on the underlying layer equal to the predetermined distance.

Example 10. The method of example 9, further including comparing the predetermined distance to a target distance; determining the predetermined distance does not meet the target distance; generating a set of process parameters by adjusting the activating energy applied to the grafting material based on the difference between the predetermined distance and the target distance; providing a further substrate having mandrels positioned on an underlying layer, and repeating the steps of depositing the grafting material on the substrate and depositing a filler material on the substrate; performing the steps of applying the activating energy to the grafting material to a further predetermined distance using the generated set of process parameters; and removing soluble portions of the filler material using the particular solvent resulting in a layer of filler material on the underlying layer equal to the further predetermined distance that meets the target distance.

Example 11. The method of one of examples 9 or 10, where the mandrels include a first plurality of mandrels having a first height formed on a first portion of the substrate and a second plurality of mandrels having a second height formed on a second portion of the substrate, where the first height is greater than the second height.

Example 12. The method of one of examples 9 to 11, where the predetermined distance is greater than the first height.

Example 13. The method of one of examples 9 to 12, where the predetermined distance is equal to the first height.

Example 14. A method of forming a pattern on a substrate, the method including: depositing a grafting material over a substrate, the substrate including a plurality of structures formed over an underlying layer formed across a working surface of a substrate, the grafting material covering exposed portions of the underlying layer without covering surfaces of the plurality of structures; depositing a fill material on the substrate that covers the grafting material; liberating a solubility-shifting acid from the grafting material by exposing the substrate to a pattern of radiation; converting a portion of the fill material to a converted fill material by diffusing the solubility-shifting acid into the fill material; and selectively removing the remaining portions of the fill material without removing the converted fill material.

Example 15. The method of example 14, where after selectively removing the remaining portions, the substrate includes a major surface including the converted fill material, the major surface being planar.

Example 16. The method of one of examples 14 or 15, where the converted fill material includes a major surface that is substantially co-planar with major surfaces of the plurality of structures.

Example 17. The method of one of examples 14 to 16, where the converted fill material covers the plurality of structures.

Example 18. The method of one of examples 14 to 17, where the converted fill material has a first thickness in a first portion of the substrate and a second thickness in a second portion of the substrate, the first thickness being different than the second thickness.

Example 19. The method of one of examples 14 to 18, where the plurality of structures further include a first plurality of structures in a first portion of the substrate and a second plurality of structures in a second portion of the substrate, the first plurality of structures including a different dimension than the second plurality of structures, and where the converted fill material covers major surfaces of the first plurality of structures without covering major surfaces of the second plurality of structures.

Example 20. The method of one of examples 14 to 19, where the converted fill material has a first thickness in a first portion of the substrate and a second thickness in a second portion of the substrate, the first thickness being greater than the second thickness and being less than a height of the plurality of structures.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Although the different steps are described in a specific order for the sake of clarity, in various embodiments, some of these steps may be performed in a different order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of planarizing a substrate, the method comprising:
receiving a substrate having structures formed on a target layer of a working surface of a substrate, the structures formed of a first material, the target layer formed of a second material different from the first material;
depositing a grafting material on the substrate, the grafting material adhering to uncovered surfaces of the target layer without adhering to surfaces of the structures, the grafting material including a solubility-shifting agent;
depositing a fill material on the substrate that covers the grafting material;
causing the solubility-shifting agent to diffuse a predetermined distance into the fill material, the solubility-shifting agent causing the fill material to become insoluble to a predetermined solvent; and
using the predetermined solvent to remove soluble portions of the fill material, remaining portions of the fill material forming a surface parallel to the working surface of the substrate.

2. The method of claim 1, wherein a top surface of the fill material after development is planar with a top surface of the structures.

3. The method of claim 1, wherein a top surface of the fill material after development has a z-height below a z-height of a top surface of the structures.

4. The method of claim 1, wherein the solubility-shifting agent is a free acid.

5. The method of claim 1, wherein the solubility-shifting agent is a thermal acid generator.

6. The method of claim 1, wherein the solubility-shifting agent is a photoacid generator.

7. The method of claim 1, wherein the grafting material includes a self-assembled monolayer (SAM).

8. The method of claim 1, wherein the grafting material includes a polymer brush.

9. A method of forming a pattern on a substrate, the method comprising:
depositing a grafting material over a substrate, the substrate having mandrels positioned on an underlying layer, the mandrels comprising a first material and the underlying layer comprising a second material, the second material being chemically different than the first material, the grafting material selectively adhering to uncovered surfaces of the underlying layer without adhering to uncovered surfaces of the mandrels, the grafting material that adheres to the underlying layer results in a uniform thickness of the grafting material on the underlying layer, the grafting material including an acid generator that releases acid in response to an activating energy;
depositing a filler material on the substrate that fills spaces defined by the mandrels, the filler material being in contact with the grafting material, the filler material contacting the grafting material, the filler material forming a horizontal interface with the grafting material, the filler material comprising a third material; and
applying the activating energy to the grafting material sufficient to activate the acid generator causing acid to diffuse a predetermined distance into the filler material, the acid rendering the filler material insoluble to a particular solvent; and
removing soluble portions of the filler material using the particular solvent resulting in a layer of filler material on the underlying layer equal to the predetermined distance.

10. The method of claim 9, further comprising comparing the predetermined distance to a target distance;
determining the predetermined distance does not meet the target distance;
generating a set of process parameters by adjusting the activating energy applied to the grafting material based on the difference between the predetermined distance and the target distance;
providing a further substrate having mandrels positioned on an underlying layer, and repeating the steps of depositing the grafting material on the substrate and depositing a filler material on the substrate;
performing the steps of applying the activating energy to the grafting material to a further predetermined distance using the generated set of process parameters; and
removing soluble portions of the filler material using the particular solvent resulting in a layer of filler material on the underlying layer equal to the further predetermined distance that meets the target distance.

11. The method of claim 9, wherein the mandrels comprise a first plurality of mandrels having a first height formed on a first portion of the substrate and a second plurality of mandrels having a second height formed on a second portion of the substrate, wherein the first height is greater than the second height.

12. The method of claim 11, wherein the predetermined distance is greater than the first height.

13. The method of claim 11, wherein the predetermined distance is equal to the first height.

14. A method of forming a pattern on a substrate, the method comprising:
depositing a grafting material over a substrate, the substrate comprising a plurality of structures formed over an underlying layer formed across a working surface of a substrate, the grafting material covering exposed portions of the underlying layer without covering surfaces of the plurality of structures;
depositing a fill material on the substrate that covers the grafting material;
liberating a solubility-shifting acid from the grafting material by exposing the substrate to a pattern of radiation;
converting a portion of the fill material to a converted fill material by diffusing the solubility-shifting acid into the fill material; and
selectively removing the remaining portions of the fill material without removing the converted fill material.

15. The method of claim 14, wherein after selectively removing the remaining portions, the substrate comprises a major surface comprising the converted fill material, the major surface being planar.

16. The method of claim 15, wherein the converted fill material comprises a major surface that is substantially co-planar with major surfaces of the plurality of structures.

17. The method of claim 15, wherein the converted fill material covers the plurality of structures.

18. The method of claim 15, wherein the converted fill material has a first thickness in a first portion of the substrate and a second thickness in a second portion of the substrate, the first thickness being different than the second thickness.

19. The method of claim 14, wherein the plurality of structures further comprise a first plurality of structures in a first portion of the substrate and a second plurality of structures in a second portion of the substrate, the first plurality of structures comprising a different dimension than the second plurality of structures, and wherein the converted fill material covers major surfaces of the first plurality of structures without covering major surfaces of the second plurality of structures.

20. The method of claim 14, wherein the converted fill material has a first thickness in a first portion of the substrate and a second thickness in a second portion of the substrate, the first thickness being greater than the second thickness and being less than a height of the plurality of structures.
